(19) United States
(12) Patent Application Publication
(10) Pub. No.: US 2003/0160300 A1
(43) Pub. Date: Aug. 28, 2003

(54) Semiconductor substrate, method of manufacturing the same and semiconductor device

(76) Inventors: Masahiro Takenaka, Nara-shi (JP); Katsumasa Fujii, Yamatokooriyama-shi (JP)

Correspondence Address: NIXON & VANDERHYE, PC, 1100 N GLEBE ROAD, 8TH FLOOR, ARLINGTON, VA, 22201-4714, US

(21) Appl. No.: 10/370,452

(22) Filed: Feb. 24, 2003

(30) Foreign Application Priority Data
Feb. 22, 2002 (JP) 2002-046789

(51) Int. Cl. H01L 29/04

(52) U.S. Cl. 257/536; 257/55; 257/616

(57) ABSTRACT

A semiconductor substrate comprising a silicon substrate with an oxide film on its surface, on which a silicon layer, a warp-relieved SiGe layer and a warped cap layer are formed in this order, a semiconductor device comprising a transistor, a diode, a capacitor and/or a bipolar transistor formed solely or in combination on the above semiconductor substrate and a method of manufacturing the above semiconductor substrate.

### CROSS-REFERENCE TO RELATED APPLICATION

This application is related to Japanese Patent Application No. 2002-46789 filed on Feb. 22, 2002, whose priority is claimed under 35 USC §119, the disclosure of which is incorporated by reference in its entirety.

### BACKGROUND OF THE INVENTION

1. Field of the Invention

The present invention relates to a semiconductor substrate, a method of manufacturing the same and a semiconductor device. More specifically, it relates to a semiconductor substrate used for manufacturing semiconductor devices in which an SiGe/Si hetero structure is formed on an SOI substrate, a method of manufacturing the same and a semiconductor device.

2. Description of Related Art

There has been known a method for improving the mobility of electrons and positive holes passing through a channel region by forming a warped SiGe pseudomorphic film on an Si substrate, relieving the warpage of the SiGe film caused by a lattice constant mismatch with the Si substrate through introduction of misfit dislocation and then forming an Si film as a cap layer on the warped SiGe film. In this Si film, warpage occurs due to a tensile force by the SiGe film having a larger lattice constant, which alters a band structure and hence the carrier mobility improves.

As a method of relieving the warpage of the SiGe film, there has been known a method of relieving the lattice by forming the SiGe film into a thickness of several μm to increase elastic energy of the warpage of the SiGe film (e.g., Y. J. Mii et al. presented in Appl. Phys. Lett. 59 (13), 1611 (1991) a method of relieving the warpage of the SiGe film by forming a concentration-graded SiGe film of about 1 μm thick in which the Ge concentration is gradually increased.).

Japanese Unexamined Patent Publication No. Hei 10 (1998)-308503 describes a method of forming a warped Si layer on an insulative substrate by making use of the above-described method. According to this publication, as shown in FIG. 4, a Ge concentration-graded SiGe film 11 of about 1 μm thick is formed on a first silicon substrate 10, on which a second SiGe film 12, an SiGe film 13 which functions as an etch stopper and a warped Si film 14 are formed. Further, a warped SiGe film 15 and a third SiGe film 16 are formed thereon and a warpless Si film 17 is formed at the top. Then, a second silicon substrate (not shown) is bonded thereto through the intervention of a silicon oxide film (not shown) and removal of the films is performed from the first silicon substrate side to the SiGe film 13. Thereby, the warped Si layer is provided on the insulative substrate.

However, by any of the above-described methods of forming the SiGe film of several μm thick to increase the elastic energy of the warpage in the SiGe film for relieving the lattice, the thickness of the SiGe film exceeds a thickness critical to obtaining a perfect crystal. As a result, an extremely large amount of defect is caused in the SiGe film.

Further, the manufacture of the thick SiGe film for the warpage relief results in a low throughput, which increases the manufacture cost.

### SUMMARY OF THE INVENTION

Even in the case where a warped SiGe film having a high Ge concentration and a thickness smaller than the critical thickness is formed on the substrate, the present invention achieves the warpage relief in the SiGe film to a high degree and hence provides an inexpensive semiconductor substrate of high throughput and a method of manufacturing the same.

The present invention provides a semiconductor substrate comprising a silicon substrate with an oxide film on its surface, on which a silicon layer, a warp-relieved SiGe layer and a warped cap layer are formed in this order.

Further, the present invention provides a method of manufacturing a semiconductor substrate comprising the steps of:

(a) forming a first SiGe layer on a first silicon substrate;

(b) introducing in the neighborhood of an interface between the first SiGe layer and the first silicon substrate an element which is electrically neutral in the first SiGe layer or the substrate and performing heat treatment to form a defect layer for warpage relief in the neighborhood of the interface between the first SiGe layer and the first silicon substrate;

(c) forming a second SiGe layer on the first SiGe layer;

(d) forming a warped cap layer on the second SiGe layer;

(e) forming a third SiGe layer as the warp-relieved SiGe layer and a silicon layer in this order on the warped cap layer;

(f) bonding a second silicon substrate with an oxide film on its surface to the resulting first silicon substrate;

(g) dividing the first and second silicon substrates at the defect layer; and

(h) removing the defect layer, the first SiGe layer and the second SiGe layer remaining on the resulting second silicon substrate to expose the warped cap layer, thereby obtaining the second silicon substrate with the oxide film on its surface, on which the silicon layer, the warp-relieved SiGe layer and the warped cap layer are formed in this order.

Furthermore, the present invention provides a semiconductor device comprising:

a semiconductor substrate comprising a silicon substrate with an oxide film on its surface, on which a silicon layer, a warp-relieved SiGe layer and a warped cap layer are formed in this order and

a transistor, a diode, a capacitor and/or a bipolar transistor formed solely or in combination on the semiconductor substrate.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic sectional view of a major part for explaining a method of manufacturing a semiconductor substrate according to the present invention;

FIG. 2 is a schematic sectional view of a major part for explaining the method of manufacturing the semiconductor substrate according to the present invention;

FIG. 3 is a schematic sectional view of a major part illustrating an embodiment of the semiconductor substrate according to the present invention; and

FIG. 4 is a schematic sectional view of a major part illustrating a prior art semiconductor substrate.

### DESCRIPTION OF THE PREFERRED EMBODIMENTS

The semiconductor substrate of the present invention is mainly comprised of a silicon substrate with an oxide film on its surface, on which a silicon layer, a warp-relieved SiGe layer, i.e., strain released SiGe layer, and a warped cap layer, i.e., strained cap layer, are formed in this order.

The silicon substrate is not particularly limited as long as it is generally used for manufacturing semiconductor devices and may be made of amorphous silicon, microcrystalline silicon, monocrystalline silicon, polycrystalline silicon or silicon in which two or more of the above-described crystal structures co-exist. Among them, a monocrystalline silicon substrate is preferable. The silicon substrate has an oxide film on its surface. The oxide film corresponds to a buried oxide film of a so-called SOI substrate. Thickness thereof may suitably be adjusted depending on properties of an intended semiconductor substrate and the magnitude of a voltage applied to a device made of the resulting semiconductor substrate. For example, the thickness may be about 50 to 1,000 nm.

The silicon layer on the oxide film is preferably formed as a substantially crystalline layer. In the silicon layer, a lattice constant increases larger than that of silicon under the influence of an SiGe layer to be formed thereon (explained later) and hence warpage is contained. The crystalline layer mentioned herein signifies a microcrystalline layer, a polycrystalline layer, a monocrystalline layer and a layer in which these crystal structures co-exist. Among them, a monocrystalline layer is preferable. A suitable thickness of the silicon layer is, for example, about 10 to 100 nm.

The warp-relieved SiGe layer on the silicon layer is preferably formed as a substantially crystalline layer. Warpage of the SiGe layer is relieved by a warped cap layer to be formed thereon (explained later). In general, where a laminated structure of SiGe/Si layers or SiGe/SiC layers is formed, warpage occurs essentially in the SiGe layer due to a difference in lattice constant between Ge and Si. In this context, the term “warp-relieved” signifies a state where the amount of the warpage is reduced. More specifically, by introducing an element to be explained later, crystal dislocation occurs in the SiGe layer and defects are caused, thereby the warpage is relieved. This SiGe layer is further subjected to heat treatment to accumulate the defects in a certain region, thereby relieving the warpage in other regions than the accumulated region. The warp-relieved SiGe layer preferably has a thickness not larger than a critical thickness which depends on the Ge concentration. For example, a suitable thickness may be about 5 to 500 nm, preferably about 10 to 300 nm. The ratio of germanium in this layer is not particularly limited, but suitably about 10 to 40 atm %. The composition ratio may vary successively or gradually within the above-described range in a thickness direction and a surface (in-plane) direction of the SiGe layer. However, the ratio is preferably fixed.

The warped cap layer on the warp-relieved SiGe layer is preferably formed as a substantially crystalline layer and warpage is contained therein. In this context, the expression “warpage is contained therein” signifies a state where a lattice constant of an element comprising the warped cap layer is smaller or larger than that of a cap layer. The warped cap layer may be made of silicon or SiC. Thickness thereof is preferably not larger than the critical thickness to prevent the generation of crystal defects. For example, a suitable thickness may be about 5 to 500 nm, in particular about 10 to 300 nm.

According to the method of manufacturing a semiconductor substrate of the present invention, to begin with, a first SiGe layer is formed on a first silicon substrate in the step (a). The first silicon substrate used in this step may be the same as those described above. The first SiGe layer may be formed by any of known methods such as CVD, sputtering, vacuum deposition, EB method and the like. In particular, the first SiGe layer is preferably formed by epitaxial growth by CVD. In this case, conditions for the film formation may be selected from those known in the art. Especially, temperature for the film formation may be, for example, about 400 to 700° C., preferably about 400 to 650° C. The first SiGe layer preferably has a thickness not larger than the critical thickness which depends on the Ge concentration. For example, a suitable thickness may be about 5 to 500 nm, preferably about 10 to 300 nm. The ratio of germanium in this layer is not particularly limited, but suitably about 10 to 40 atm %. The composition ratio may vary successively or gradually within the above-described range in a thickness direction and a surface (in-plane) direction of the SiGe layer. However, the ratio is preferably fixed.

In the step (b), an element which is electrically neutral in the first SiGe layer or the first silicon substrate is introduced in the neighborhood of an interface between the first SiGe layer and the first Si substrate. In this context, “an element which is electrically neutral in the first SiGe layer or the first silicon substrate” signifies hydrogen, those belong to the fourth group of the periodic table such as carbon, silicon, germanium and tin, those belong to the zero group such as He, Ne, Ar, Kr and Xe, and the like. Among them, hydrogen is preferable. A method of introducing the element is not particularly limited, but ion implantation is preferable. Conditions for the ion implantation, for example, a dose amount and an implantation energy, may suitably be selected depending on the type of the element and the thickness of the first SiGe layer and the like. For example, the element can be introduced under the conditions used in a technique called Smart Cut method (a registered trademark of SOITEC, see Japan Electronics and Information Technology Industries Association, “Search Report V on the Trend of Multilayer Integration Technology”, 98-KI-18, pp. 7-9). More specifically, the ion implantation is carried out in a dose amount of about 1×10¹⁵ to 1×10¹⁷ cm⁻², preferably about 1×10¹⁶ to 1×10¹⁷ cm⁻². The implantation energy is preferably set such that an implantation peak appears in the neighborhood of an interface between the first SiGe layer and the first silicon substrate, in particular on the substrate side of the interface. More specifically, it is preferred to establish the peak at a position of about 50 nm or more in depth (preferably about 50 to 100 nm) from the interface towards the silicon substrate for the purposes of preventing the defects in the SiGe layer and avoiding thickness reduction of the SiGe layer. For example, the implantation energy may be about 20 to 150 keV. More specifically, where the thickness of the SiGe layer is about 200 to 250 nm and hydrogen is used, the implantation energy is about 20 to 35 keV. Upon implantation, an insulating film such as an oxide film or a nitride film may be formed as a cover film on the surface of the SiGe layer to implant ions into a shallower position through the cover film.

Subsequently, heat treatment is performed. A method and conditions of the heat treatment may be selected from those known in the art. Specifically, furnace annealing or lamp annealing is carried out in an atmosphere of inert gas, ambient air, nitrogen gas, oxygen gas or hydrogen gas at a temperature in the range of 600 to 900° C. for about 5 to 30 minutes, more specifically at 800° C. for about 7 to 10 minutes. The heat treatment may be carried out through a cover film as described above with a view to flattening the surface of the SiGe layer.

Through these steps, the defect layer is formed at the interface between the first SiGe layer and the first silicon substrate. Further, the crystallinity of the SiGe layer in a region where the ions have passed is recovered. Thereby, the warpage of the SiGe layer is relieved.

Then, in the step (c), a second SiGe layer is formed on the first SiGe layer. The second SiGe layer may be formed in the same manner as the method for forming the first SiGe layer to have the same thickness and composition.

In the step (d), the warped cap layer is formed on the second SiGe layer. The warped cap layer may be formed in accordance with the method for forming the first SiGe layer depending on the type of the warped cap layer.

In the step (e), a third SiGe layer as the warp-relieved silicon substrate and the silicon layer are formed on the warped cap layer. The third SiGe layer may be formed in the same manner as the method for forming the first SiGe layer. The silicon layer may be formed by a known method such as CVD, sputtering, vacuum deposition or EB method in accordance with the method for forming the SiGe layer. In particular, the silicon layer is preferably formed by epitaxial growth by CVD. In this case, conditions for the film formation may be selected from those known in the art. Especially, temperature for the film formation is, for example, about 400 to 700° C., preferably about 400 to 650° C. If the warped cap layer is bonded to a second silicon substrate through the intervention of an oxide film as described later without forming the third SiGe layer and the silicon layer, the warpage of the warped cap layer may possibly be relieved. The reason why the third SiGe layer and the silicon layer are formed in this step is to prevent the warpage relief.

In the step (f), a second silicon substrate as the silicon substrate is bonded to the resulting first silicon substrate through the intervention of the oxide film. The oxide film may be formed on the surface of the first silicon substrate by heat treatment or on the surface of the second silicon substrate by thermal oxidation, CVD or a method known in the art. However, the latter is preferable. If the surface of the SiGe layer is oxidized, the Ge concentration in the SiGe layer increases depending on the degree of the oxidation, for silicon is more easily oxidized than germanium. The second silicon substrate used herein may be made of the same material as that of the first silicon substrate.

Before bonding the substrates, it is preferred to clean the surfaces of the substrates because the existence of foreign matters on the bonding surfaces may cause void defects and decrease manufacturing yield. The cleaning may be performed by a method known in the art using water, an inorganic or organic solvent or the like. The bonding may be carried out by a known bonding technique. For example, usable are a method of bonding the substrates at room temperature and causing van der Waals coupling, followed by heating to bond them firmly, a method described in Japan Electronics and Information Technology Industries Association, “Search Report V on the Trend of Multilayer Integration Technology”, 98-KI-18, p. 12, a method described by N. Sato et al. in Appl. Phys. Lett. 65 (15), p 1924 (1994) and a method of Michael Allen, IEEE, SPECTRUM, June, 37 (1997).

In the step (g), the first and second silicon substrates are divided at the defect layer. This is carried out by performing heat treatment at a low temperature of 400 to 600° C. to grow in the defect layer microcavities derived from the element introduced as described above and separating the substrates. In this case, the separation is preferably performed by the Smart Cut method described above (see Japan Electronics and Information Technology Industries Association, “Search Report V on the Trend of Multilayer Integration Technology”, 98-KI-18, p. 7).

In the step (h), the defect layer, the first SiGe layer and the second SiGe layer remaining on the resulting second silicon substrate are removed. That is, after the above-mentioned separation, part of the defect layer remains on the surface of the second silicon substrate. Accordingly, the remaining defect layer is removed. Further, the first and second SiGe layers are completely removed to expose the warped silicon layer. The removal of the layers may be carried out by a known method such as wet etching using an acidic or alkaline solution, dry etching such as sputtering and RIE or CMP. Upon removing the layers, it is preferred to flatten the resulting surface. Therefore, CMP is preferably adopted. After the separation or the removal of the layers, it is preferred to perform heat treatment at a high temperature of about 800 to 1200° C. to strengthen the part bonded through the intervention of the oxide film in the previous step. Thereby, a substrate with the warped cap layer on its surface is obtained.

After the above-described steps, device isolation regions, gate insulating films, gate electrodes, sidewall spacers, source/drain regions and interlayer insulating films may optionally be formed on the resulting semiconductor substrate by a known process for manufacturing semiconductor devices. Thereby, a semiconductor device is completed.

The semiconductor device of the present invention generally includes a device isolation region (e.g., a LOCOS film, an STI (shallow trench isolation) film and a trench device isolation film) formed on the above-described substrate. Further, various semiconductor elements known in the art such as a MOS transistor, a diode, a capacitor and a bipolar transistor are formed solely or in combination. In particular, a CMOS transistor including a PMOS transistor and an NMOS transistor is preferably formed.

For example, in the MOS transistor, a gate oxide film, a gate electrode and a source/drain region are made of common material to have a common thickness by a common method for manufacturing the semiconductor device. The gate electrode may be provided with sidewall spacers and the source/drain region may have an LDD structure or a DDD structure.

Hereinafter, embodiments of a semiconductor substrate, a method for forming the same and a semiconductor device according to the present invention are explained with reference to the figures.

First, in a preliminary treatment, a first p-type Si (100) substrate 9 is subjected to ashing by boiling in sulfuric acid and RCA washing and then a naturally oxidized film on the surface thereof is removed using 5% diluted hydrofluoric acid. On the thus treated first Si (100) substrate 9, a first Si_{0.8}Ge0.2 pseudomorphic film 1 having a Ge concentration of 20% and a thickness of 200 nm is epitaxially grown at 500° C. in a low pressure chemical vapor deposition (LP-CVD) apparatus using germane (GeH₄) and disilane (Si₂H₆) as raw materials. The first Si_{0.8}Ge_{0.2} film 1 formed under these conditions has a thickness not larger than the critical thickness.

To the resulting substrate 9, hydrogen ions are implanted under the Smart Cut conditions of an implantation energy of 25 keV, a dose amount of 6×10¹⁶/cm² and a tilt angle of 7°. After RCA washing, annealing is performed at 800° C. for 10 minutes. Thereby, an oval-shaped defect layer 6 is formed at a position of about 50 nm inside the first Si substrate 9 from an interface between the first Si substrate 9 and the first SiGe film 1. Thus, warpage of the first SiGe film 1 due to lattice mismatch is almost completely relieved (90% or more).

Subsequently, on the first SiGe film 1, a second Si_{0.8}Ge_{0.2} film 2 of a virtual lattice structure having a Ge concentration of 20% and a thickness of 200 nm is epitaxially grown at 500° C. in the LP-CVD apparatus using germane (GeH₄) and disilane (Si₂H₆) as raw materials.

On the second SiGe film 2, a warped Si pseudomorphic film 3 having a thickness of 20 nm is epitaxially grown at 500° C. in the LP-CVD apparatus using disilane (Si₂H₆) as a raw material.

Then, on the warped Si film 3, a third Si_{0.8}Ge_{0.2} film 4 of a virtual lattice structure having a Ge concentration of 20% and a thickness of 200 nm is epitaxially grown at 500° C. in the LP-CVD apparatus using germane (GeH₄) and disilane (Si₂H₆) as raw materials.

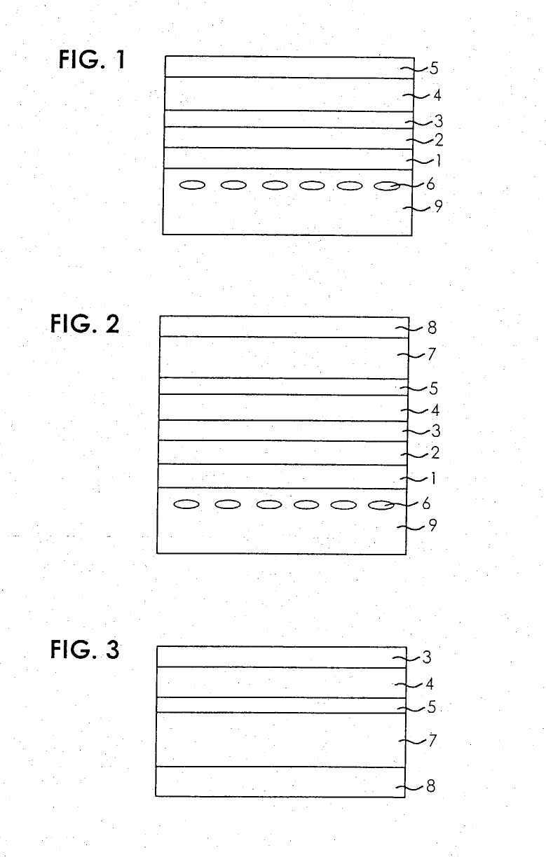

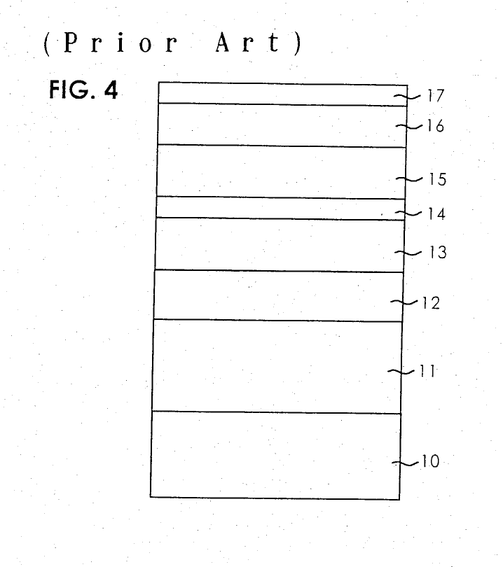

Further, an Si film 5 is formed on the third SiGe film 4. Thus, the substrate shown in FIG. 1 is obtained.

Then, on a second Si substrate 8, an SiO₂ film 7 of about 400 nm thick is formed. The SiO₂ film 7 is faced to the Si film 5 formed on the first Si substrate and they are bonded. Thus, the substrate shown in FIG. 2 is obtained.

Subsequently, the substrates are divided at the defect layer 6 in the first Si substrate 9 by the Smart Cut method. Thereafter, the first and second SiGe films 1 and 2 are removed by selective etching.

Thereby, the semiconductor substrate shown in FIG. 3 having an SiGe/Si hetero structure on an insulator is obtained.

According to the above-described method of manufacturing the semiconductor substrate, the defect layer is formed within the first Si substrate. The defect layer causes slipping towards the first Si substrate surface, which generates misfit dislocation of high density at an interface between the first Si substrate and the first SiGe layer. As a result, the warpage of the first SiGe layer is almost completely relieved.

Further, since the second SiGe layer is formed on the first SiGe layer whose warpage has almost been completely relieved, the warpage energy of the second SiGe layer becomes very small. As a result, combined with small-amplitude roughness, the surface of the second SiGe film becomes very smooth.

Moreover, if the second SiGe layer is formed at a relatively low temperature, the defect density is advantageously reduced.

As compared with the method of lattice relief by forming the SiGe layer into a thickness of several μm as a buffer layer to increase the elastic energy of its warpage, the present invention allows almost complete warpage relief by forming a thin SiGe layer. Therefore, excellent throughput and low manufacture cost are achieved.

In the thus manufactured substrate, tensile warpage is contained in the warped silicon layer lying at the top. Accordingly, by forming a gate oxide film and a gate electrode thereon, a channel is formed within the warped silicon layer containing the tensile warpage. Therefore, the mobility of electrons and positive holes is improved as compared with that in normal Si, which allows realization of a high-speed CMOS integrated circuit.

According to the present invention, is realized a warp-relieved SiGe/warped Si hetero structure in which the warpage of the SiGe film having a thickness not larger than the critical thickness is almost completely relieved. In other words, a silicon layer having favorable warpage and few crystal defects is provided. Further, a semiconductor device intended to high-speed mobility can be manufactured in which a channel is formed in the warped silicon layer containing the tensile warpage.

Moreover, by bonding the second silicon substrate to the first silicon substrate on which the SiGe layers and the cap layer are formed, the warp-relieved SiGe/warped Si hetero structure is efficiently formed on a so-called SOI substrate. Thus, excellent throughput and low manufacture cost are achieved.

What is claimed is:

1. A semiconductor substrate comprising a silicon substrate with an oxide film on its surface, on which a silicon layer, a warp-relieved SiGe layer and a warped cap layer are formed in this order.

2. A semiconductor substrate according to claim 1, wherein the warped cap layer is an Si layer or an SiC layer.

3. A semiconductor substrate according to claim 1, wherein the warp-relieved SiGe layer has a Ge concentration of 10 to 40 atm %.

4. A method of manufacturing a semiconductor substrate comprising the steps of:
(a) forming a first SiGe layer on a first silicon substrate;
(b) introducing in the neighborhood of an interface between the first SiGe layer and the first silicon substrate an element which is electrically neutral in the first SiGe layer or the substrate and performing heat treatment to form a defect layer for warpage relief in the neighborhood of the interface between the first SiGe layer and the first silicon substrate;
(c) forming a second SiGe layer on the first SiGe layer;
(d) forming a warped cap layer on the second SiGe layer;
(e) forming a third SiGe layer as the warp-relieved SiGe layer and a silicon layer in this order on the warped cap layer;
(f) bonding a second silicon substrate with an oxide film on its surface to the resulting first silicon substrate;
(g) dividing the first and second silicon substrates at the defect layer; and
(h) removing the defect layer, the first SiGe layer and the second SiGe layer remaining on the resulting second silicon substrate to expose the warped cap layer, thereby obtaining the second silicon substrate with the oxide film on its surface, on which the silicon layer, the warp-relieved SiGe layer and the warped cap layer are formed in this order.

5. A method according to claim 4, wherein the electrically neutral element is introduced in the step (b) in the silicon substrate side of the interface between the first SiGe layer and the first silicon substrate.

6. A method according to claim 4, wherein the electrically neutral element is hydrogen, helium, argon or neon.

7. A method according to any one of claim 4, wherein the electrically neutral element is introduced by ion implantation in a dose amount of 1×10¹⁶ to 1×10¹⁷ cm⁻².

8. A semiconductor device comprising:
a semiconductor substrate comprising a silicon substrate with an oxide film on its surface, on which a silicon layer, a warp-relieved SiGe layer and a warped cap layer are formed in this order and
a transistor, a diode, a capacitor and/or a bipolar transistor formed solely or in combination on the semiconductor substrate.
